(19) United States
(12) Patent Application Publication
(10) Pub. No.: US 2026/0247830 A1
(43) Pub. Date: Aug. 20, 2026

(54) LIGHT-EMITTING ELEMENT, PRODUCTION METHOD THEREFOR, AND DISPLAY DEVICE

(71) Applicant: Sharp Display Technology Corporation, Kameyama City, Mie (JP)

(72) Inventors: Takahiro ADACHI, Sakai City (JP); Yasushi ASAOKA, Sakai City (JP)

(21) Appl. No.: 19/162,090

(22) PCT Filed: Mar. 9, 2023
(86) PCT No.: PCT/JP2023/009026

§ 371 Date: Sep. 4, 2025

(51) Int. Cl. H10K 59/00; H10K 59/12

(52) U.S. Cl. CPC H10K 59/771; H10K 59/1201

(57) ABSTRACT

The disclosure realizes a technique for increasing a reliability of a light-emitting element while supplying an appropriate amount of current to a light-emitting region for light emission. In the light-emitting element, a first charge transport layer is continuous from a light-emitting region to a second region, and a light-emitting layer is continuous from the light-emitting region to a first region. The light-emitting region and the first region of the first charge transport layer have a higher electrical conductivity than the second region of the first charge transport layer

### TECHNICAL FIELD

The disclosure relates to a light-emitting element, a manufacturing method therefor, and a display device.

### BACKGROUND ART

As an image display device, in the related art, there is known an organic electroluminescence image display device. The organic electroluminescence image display device includes, for example, an anode electrode, a hole transport layer, a light-emitting layer, an electron transport layer, and a cathode electrode on a substrate, and is configured such that a plurality of light-emitting elements each function as a red, green, and blue subpixel. In the related art, various techniques for improving the reliability of each of the plurality of light-emitting elements are studied for the organic electroluminescence image display device.

As such a known technique, there is known a technique in which an electrical conductivity of a region other than a light-emitting region is decreased compared to that of the light-emitting region to reduce an excess current and suppress a deterioration of a light-emitting element (for example, see PTL 1).

### CITATION LIST

### Patent Literature

PTL 1: WO 2013/011599

### SUMMARY

### Technical Problem

On the other hand, in the organic electroluminescence image display device, power saving is also required, and an optimization of a current supplied to a light-emitting region is also studied. Therefore, there is a demand for a technique for increasing the reliability of a light-emitting element while supplying a current to a light-emitting region for light emission.

An object of an aspect of the disclosure is to realize a technique for increasing a reliability of a light-emitting element while supplying an appropriate amount of current to a light-emitting region for light emission.

### Solution to Problem

In order to solve the above problem, a light-emitting element according to the disclosure is a light-emitting element including an electrode, a charge transport layer, and a light-emitting layer, the electrode, the charge transport layer, and the light-emitting layer being disposed to overlap in this order in a light-emitting region partitioned by at least a bank, in which the charge transport layer is formed in the light-emitting region, a first region adjacent to an outer side of the light-emitting region, and a second region adjacent to a further outer side of the first region, in a plan view, the light-emitting layer is formed in at least the light-emitting region and the first region in a plan view, and in at least one direction in a plan view, the light-emitting region and the first region of the charge transport layer have a higher electrical conductivity than the second region of the charge transport layer.

In order to solve the above problem, a manufacturing method of a light-emitting element according to the disclosure is a manufacturing method of the above-described light-emitting element, the method including irradiating a portion corresponding to each of the first region and the second region to be formed in a layer formed of a charge transport material with an electrical conductivity varying when irradiated with active light rays, with active light rays having a specific cumulative irradiation amount according to electrical conductivities of the first region and the second region.

In order to solve the above problem, a display device according to the disclosure includes the above-described light-emitting element.

### Advantageous Effects of Disclosure

According to the disclosure, it is possible to increase a reliability of a light-emitting element while supplying an appropriate amount of current to a light-emitting region for light emission.

### BRIEF DESCRIPTION OF DRAWINGS

FIG. 1 is a diagram schematically illustrating an entire configuration of an example of a display device according to the disclosure.

FIG. 2 is a diagram schematically illustrating a cross-sectional structure of main portions in the display device of FIG. 1.

FIG. 3 is a plan view schematically illustrating an example of an arrangement of a light-emitting element in the display device of FIG. 1.

FIG. 4 is a diagram schematically illustrating a cross-sectional structure obtained when the light-emitting element according to a first embodiment of the disclosure is taken along A-A′ line of FIG. 3.

FIG. 5 is a flowchart illustrating an example of a flow of a process of manufacturing the light-emitting element of FIG. 4.

FIG. 6 is a flowchart illustrating an example of a flow of a process of preparing a first charge transport layer and a light-emitting layer in FIG. 5.

FIG. 7 is a diagram schematically illustrating a cross-sectional structure obtained when a light-emitting element according to a second embodiment of the disclosure is taken along B-B′ line of FIG. 3.

FIG. 8 is a diagram schematically illustrating a cross-sectional structure obtained when the light-emitting element according to the second embodiment of the disclosure is taken along A-A′ line of FIG. 3.

FIG. 9 is a diagram schematically illustrating a cross-sectional structure obtained when a light-emitting element according to a third embodiment of the disclosure is taken along A-A′ line of FIG. 3.

FIG. 10 is a diagram schematically illustrating a cross-sectional structure obtained when the light-emitting element according to the third embodiment of the disclosure is taken along B-B′ line of FIG. 3.

FIG. 11 is a diagram schematically illustrating a cross-sectional structure obtained when a light-emitting element according to a fourth embodiment of the disclosure is taken along A-A′ line of FIG. 3.

FIG. 12 is a diagram schematically illustrating a cross-sectional structure of main portions of a light-emitting element according to a fifth embodiment of the disclosure.

### DESCRIPTION OF EMBODIMENTS

### Display Device

A display device according to the disclosure includes a light-emitting element described below. The display device according to the disclosure may be configured in much the same way as various known display devices as long as the display device includes the light-emitting element described below. The display device according to the disclosure will be described with reference to the drawings.

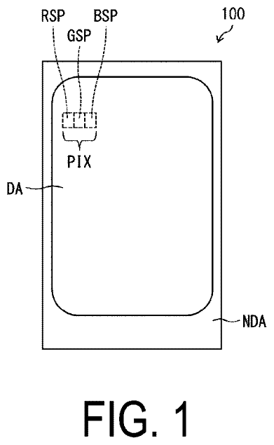

FIG. 1 is a diagram schematically illustrating an entire configuration of an example of a display device according to the disclosure. As illustrated in FIG. 1, a display device 100 includes a frame region NDA and a display region DA. A plurality of pixels PIX are provided in the display region DA of the display device 100, and each pixel PIX includes a red subpixel RSP, a green subpixel GSP, and a blue subpixel BSP. The configuration of the pixel of the display device in the disclosure is not limited to the above-described configuration. In the display device of the disclosure, for example, one pixel PIX may further include a subpixel of another color in addition to the red subpixel RSP, the green subpixel GSP, and the blue subpixel BSP.

Note that herein, configurations related to different colors among similar basic configurations are denoted by reference signs indicating colors added to a reference sign of the basic configurations. For example, a configuration related to red is denoted by R, a configuration related to green is denoted by G, and a configuration related to blue is denoted by B.

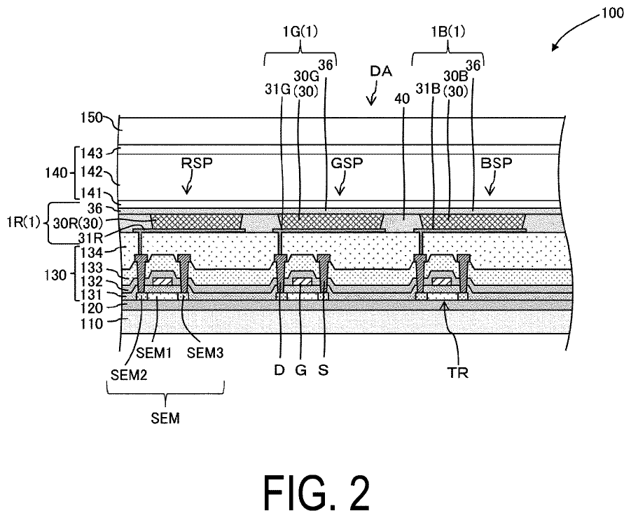

FIG. 2 is a diagram schematically illustrating a cross-sectional structure of main portions of the display device 100 in FIG. 1. As illustrated in FIG. 2, in the display region DA of the display device 100, a barrier layer 120, a thin film transistor layer 130 including transistors TR, a red light-emitting element 1R, a green light-emitting element 1G, a blue light-emitting element 1B, and a bank (transparent resin layer) 40, a sealing layer 140, and a function film 150 are provided on a substrate 110. Note that a configuration in which the substrate 110, the barrier layer 120, and the thin film transistor layer 130 illustrated in FIG. 2 are provided in this order from the substrate 110 side is also referred to as an “active matrix substrate”.

The red subpixel RSP includes the red light-emitting element 1R, the green subpixel GSP includes the green light-emitting element 1G, and the blue subpixel BSP includes the blue light-emitting element 1B. A light-emitting element 1 of each color has a similar configuration except for a material of the light-emitting layer. The configuration of the light-emitting element 1 will be described below.

The substrate 110 may be, for example, a resin substrate made of a resin material such as polyimide, or may be a glass substrate.

The barrier layer 120 is a layer that prevents foreign matters such as water and oxygen from entering the transistors TR, the red light-emitting element 1R, the green light-emitting element 1G, and the blue light-emitting element 1B. For example, the barrier layer 120 may include a silicon oxide film, a silicon nitride film, or a silicon oxynitride film formed by CVD, or a layered film thereof.

The thin film transistor layer 130 includes a portion including the transistor TR and a portion not including the transistor TR. At a portion other than the portions including the transistors TR in the thin film transistor layer 130, inorganic insulating films 131 to 133 and a flattening film 134 are configured to overlap each other in this order from the substrate 110 side. The portion including the transistor TR in the thin film transistor layer 130 includes a semiconductor film SEM, the inorganic insulating film 131, a gate electrode G, the inorganic insulating film 132, the inorganic insulating film 133, a source electrode S, a drain electrode D, and the flattening film 134. The semiconductor film SEM includes a drain region SEM2 and a source region SEM3 that are doped with an impurity such as P (phosphorus), and a channel region SEM1 between the drain region SEM2 and the source region SEM3.

The inorganic insulating films 131 to 133 can be constituted by, for example, a silicon oxide film, a silicon nitride film, or a silicon oxynitride film formed by CVD, or a layered film thereof. The inorganic insulating films 131 to 133 may be of the same type or different types.

The flattening film 134 can be made of a coatable organic material such as polyimide and acrylic.

The semiconductor film SEM is made of, for example, low-temperature polysilicon (LTPS) or may be made of an oxide semiconductor (for example, an In-Ga-Zn-O based semiconductor). In the present embodiment, the transistor TR has, for example, a top gate structure. Note that in the disclosure, the transistor TR may have a bottom gate structure.

The gate electrode G, the source electrode S, and the drain electrode D are all constituted by a single layer film or a layered film of a metal. Examples of the metal include aluminum, tungsten, molybdenum, tantalum, chromium, titanium, and copper.

Note that the thin film transistor layer 130 is provided with a control circuit including the transistors TR each of which controls a respective one of the red light-emitting element 1R, the green light-emitting element 1G, and the blue light-emitting element 1B that respectively correspond to the red subpixel RSP, the green subpixel GSP, and the blue subpixel BSP.

The red light-emitting element 1R includes a first electrode 31R that is an upper layer overlying the flattening film 134, a light-emitting function layer 30R including the red light-emitting layer, and a second electrode 36 in this order in the layering direction. Similarly, the green light-emitting element 1G includes a first electrode 31G that is an upper layer overlying the flattening film 134, a light-emitting function layer 30G including the green light-emitting layer, and the second electrode 36 in this order in the layering direction. The blue light-emitting element 1B also includes a first electrode 31B that is an upper layer overlying the flattening film 134, a light-emitting function layer 30B including the blue light-emitting layer, and the second electrode 36 in this order in the layering direction.

The sealing layer 140 is a transparent film and, for example, may be constituted by an inorganic sealing film 141 covering the second electrode 36, an organic film 142 that is an upper layer overlying the inorganic sealing film 141, and an inorganic sealing film 143 that is an upper layer overlying the organic film 142. The sealing layer 140 prevents foreign matters such as water and oxygen from penetrating into the red light-emitting element 1R, the green light-emitting element 1G, and the blue light-emitting element 1B.

Here, each of the inorganic sealing film 141 and the inorganic sealing film 143 is an inorganic film and can be constituted by, for example, a silicon oxide film, a silicon nitride film, a silicon oxynitride film, or a layered film thereof. The inorganic film is formed by CVD, for example. The organic film 142 is a transparent organic film having a flattening effect, and can be made of a coatable organic material such as acrylic, for example.

The function film 150 is a film with at least one function selected from the group consisting of an optical compensation function, a touch sensor function, and a protection function, for example.

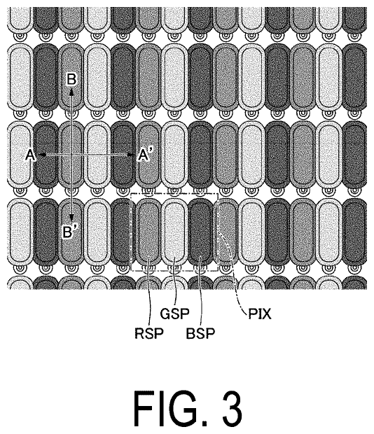

FIG. 3 is a plan view schematically illustrating an example of an arrangement of the light-emitting element 1 in the display device 100 of FIG. 1. In FIG. 3, an arrow A-A′ indicates a first direction which is one direction in an alignment direction of the light-emitting elements in which light-emitting elements are arranged in a planar shape in a display element. In FIG. 3, an arrow B-B′ indicates a second direction intersecting (orthogonal to) the first direction, and the second direction is the other direction in the alignment direction of the light-emitting elements. As illustrated in FIG. 3, the display device 100 is configured such that the pixels PIX are repeatedly arranged in each of the first direction and the second direction. Each pixel PIX is a rectangular region in which the red subpixel RSP, the green subpixel GSP, and the blue subpixel BSP are arranged along the first direction. In the second direction, the subpixels having the same color in adjacent pixels PIX are arranged. That is, in the second direction, the red subpixels RSP are arranged, the green subpixels GSP are arranged, and the blue subpixels BSP are arranged.

Thus, in the display device 100, the light-emitting layer for one pixel is separate-patterned into three colors of R, G, and B, and the light-emitting elements of R, G, and B are arranged in one pixel.

### Light-Emitting Element

The light-emitting element of the disclosure will be described. The light-emitting element according to an embodiment of the disclosure includes a light-emitting layer and a charge transport layer. The light-emitting element has a structure in which function layers related to light emission are layered. Examples of the light-emitting element include an OLED and a QLED.

In at least one direction when the light-emitting element is viewed in a plan view, the light-emitting element according to the disclosure includes a specific region in which the charge transport layer has different electrical conductivities. The light-emitting element of the disclosure can be configured in various ways within a range having such features, and can exhibit various effects due to the various configurations. The light-emitting element of the disclosure will be described below for each embodiment with reference to the drawings.

### First Embodiment

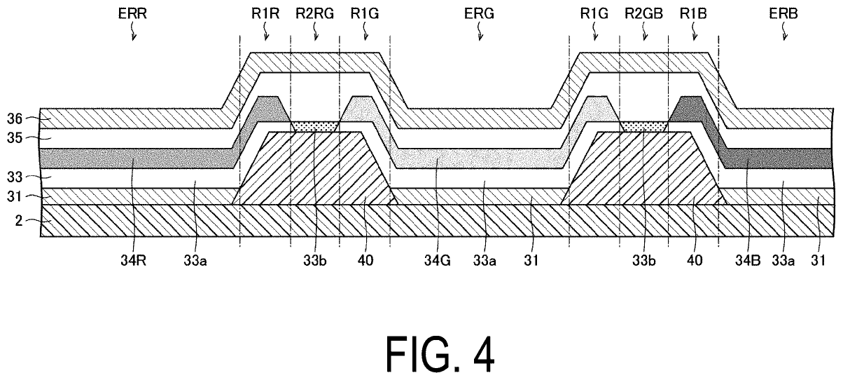

FIG. 4 is a diagram schematically illustrating a cross-sectional structure obtained when a light-emitting element according to a first embodiment of the disclosure is taken along A-A′ line of FIG. 3. FIG. 4 illustrates the light-emitting element of each color of R, G, and B. As illustrated in FIG. 4, the light-emitting element of each color of R, G, and B is formed on the substrate 2 partitioned by the bank 40. The substrate 2 is configured to include the substrate 110, the barrier layer 120, and the thin film transistor layer 130 described above, and FIG. 4 schematically illustrates the flattening film 134 in the vicinity of the light-emitting element for the substrate 2. The light-emitting element of each color includes a first electrode 31, a first charge transport layer 33, a light-emitting layer 34, a second charge transport layer 35, and a second electrode 36, and has the same configuration except that the light-emitting layer 34 of each color is included.

The bank 40 is placed on the substrate 2. The bank 40 extends in, for example, each of a first direction and a second direction to partition each subpixel. The bank has, for example, a trapezoidal cross-sectional shape.

The first electrode 31 is disposed on a region partitioned by the bank 40, on the substrate 2. The first electrode 31 is appropriately selected from, for example, a light-transmissive electrode and a reflective electrode. The light-transmissive electrode is formed of an electrically conductive light-transmissive material that transmits visible light. Examples of the material of the light-transmissive electrode include indium tin oxide (ITO), indium zinc oxide (IZO), ZnO, aluminum-doped zinc oxide (AZO, also referred to as ZAO), boron-doped zinc oxide (BZO), and fluorine-doped tin oxide (FTO). For the reflective electrode, an electrically conductive light-reflective material having a high visible light reflectivity is suitably used. Examples of the material of the reflective electrode include metals and alloys. Examples of the metal include Al, Cu, Au, and Ag, and examples of the alloy include MgAg. The reflective electrode may be configured by layering a layer formed of the light-transmissive material and a layer formed of the light-reflective material.

Three types of regions, namely, a light-emitting region ER, a first region R1, and a second region R2 are set as regions in the light-emitting element when the light-emitting element is seen in a plan view, and based on such regions, a positional relationship of each layer of the light-emitting element will be described below. The light-emitting region ER is a region in which the first electrode 31 is disposed, and is a region from one boundary to the other boundary between the bank 40 and the first electrode 31 in FIG. 4. The first region R1 is adjacent to the light-emitting region ER and extends from the boundary between the bank 40 and the first electrode 31 to one edge portion of a top face of the bank 40 via an inclined surface of the bank 40. The second region R2 is a region of a top portion of the bank 40, adjacent to the first region R1, and is a region from one edge portion to the other edge portion of the bank 40 in FIG. 4.

That is, in FIG. 4, the first electrode 31 is formed in the light-emitting region ER.

The first charge transport layer 33 is formed continuously on the first electrode 31 and the bank 40. The first charge transport layer 33 illustrated in FIG. 4 is a hole transport layer, for example. The first charge transport layer 33 includes a first conductive portion 33a and a second conductive portion 33b. The first conductive portion 33a is a portion formed in the light-emitting region ER and the first region R1, out of the first charge transport layer 33. The second conductive portion 33b is a portion formed in the second region R2, out of the first charge transport layer 33. The first conductive portion 33a and the second conductive portion 33b are adjacent to each other. Thus, the first charge transport layer 33 is formed by the light-emitting region ER, the first region R1 adjacent to the outside of the light-emitting region ER, and the second region R2 adjacent to the outside of the first region R1, along the first direction when the light-emitting element is seen in a plan view.

The first conductive portion 33a and the second conductive portion 33b both include the same charge transport material. The charge transport material is a material having a charge transport ability and having an adjustable electrical conductivity after the layer of the charge transport material is formed, and is, for example, a material whose electrical conductivity is changed by ultraviolet rays applied to the layer of the charge transport material. Examples of the charge transport material include organic compound-based materials. Examples of the organic compound-based material include polyphenylenes, polyphenylenevinylenes, polyfluorenes, polyanilines, polypyrroles, polyacetylenes, polythiophenes, triarylamines, triphenylamines, triphenylbenzenes, oxadiazoles, benzoxazoles, thioxanthenes, and derivatives thereof. A material that exhibits a desired function of the charge transport layer to be formed is employed for the charge transport material from among the above materials.

The electrical conductivity of the first conductive portion 33a is appropriately determined according to an electrical characteristic and an optical characteristic of the light-emitting element. The electrical conductivity of the first conductive portion 33a is appropriately set within a range in which the first charge transport layer 33 exhibits a desired function and an effect of the disclosure are obtained. If the electrical conductivity of the first conductive portion 33a is too low, charges may concentrate on the light-emitting element, and thus, the element lifetime may be shortened. The electrical conductivity of the first conductive portion 33a is preferably 10 10 S/m or greater, more preferably 10⁻⁸ S/m or greater, and even more preferably 10⁻S/m or greater, from the viewpoint of suppressing the concentration of charges in the light-emitting element. The electrical conductivity of the first conductive portion 33a is preferably as high as possible from the viewpoint of the electrical characteristic and the optical characteristic of the light-emitting element, and may be, for example, 103 S/m or less from the viewpoint of sufficiently exhibiting the desired charge transport function in the first charge transport layer 33.

The second conductive portion 33b has a lower electrical conductivity than the first conductive portion 33a. The electrical conductivity of the second conductive portion 33b is preferably 10⁻⁵ S/m or less, more preferably 10⁻⁸ S/m or less, and even more preferably 10⁻¹⁰ S/m or less, from the viewpoint of preventing energization from the second conductive portion 33b to the second electrode 36. The electrical conductivity of the second conductive portion 33b is preferably as low as possible, and may be, for example, 10⁻¹² S/m or greater.

The electrical conductivity (σa) of the first conductive portion 33a is preferably higher than the electrical conductivity (σb) of the second conductive portion 33b by 10% or greater (σa≥1.1×σb), more preferably higher by 50% or greater (σa≥1.5×σb), and still more preferably higher by 100% or greater (σa≥2×σb), from the viewpoint of suppressing the concentration of charges in the light-emitting element.

Note that from the viewpoint of further enhancing the effect of the disclosure, it is more preferable to design both the conductive portions, based on a ratio between the electrical conductivities of the conductive portions than to design both the conductive portions, based on an absolute value of the electrical conductivity of each of the conductive portions.

The electrical conductivity of the first conductive portion 33a is preferably as high as possible within a range in which the above-described effects of the disclosure can be obtained.

For example, from the viewpoint of sufficiently exhibiting the desired function of the first charge transport layer 33 and from the viewpoint of reaching the limit of the effect, the electrical conductivity of the first conductive portion 33a may be higher than the electrical conductivity of the second conductive portion 33 b by 200% or less (σa≤3×σb).

The electrical conductivity of the first conductive portion 33a can be adjusted by irradiation with ultraviolet rays as described below in the description of a manufacturing method described below. The electrical conductivities of the first conductive portion 33a and the second conductive portion 33b can be determined from an evaluation of conductivity distributions in a cross section of the first charge transport layer 33 by a conductive-probe atomic force microscopy.

The light-emitting layer 34 of each color is formed in the light-emitting region ER and the first region R1. For example, as illustrated in FIG. 4, along the first direction, a red light-emitting layer 34R, a green light-emitting layer 34G, and a blue light-emitting layer 34B are disposed. The red light-emitting layer 34R is formed in a light-emitting region ERR and a first region R1R adjacent thereto. The green light-emitting layer 34G is formed in a light-emitting region ERG adjacent to the light-emitting region ERR and first regions R1G and RIG adjacent thereto via the bank 40. The blue light-emitting layer 34B is formed in a light-emitting region ERB adjacent to the light-emitting region ERG and a first region R1B adjacent thereto via the bank 40.

The light-emitting layer 34 of each color includes a thick edge portion in the first direction. The thicker edge portion of the light-emitting layer 34 is located at the edge portion of the top face of the bank 40 of the first region R1 in the first direction. The thickness of the edge portion of the light-emitting layer 34 is preferably greater than the thickness of the other portion of the light-emitting layer 34 (for example, the portion on the light-emitting region ER) from the viewpoint of suppressing the concentration of charge on the edge portion of the top face of the bank 40. From such a viewpoint, the thickness of the edge portion of the light-emitting layer 34 is preferably 1.3 times or greater, more preferably 1.5 times or greater, and still more preferably 2 times or greater the thickness of the light-emitting layer 34 on the light-emitting region ER. From the above viewpoint, the thickness of the edge portion of the light-emitting layer 34 is preferably as large as possible, and may be, for example, 20 times or less the thickness of the light-emitting layer 34 on the light-emitting region ER from the viewpoint of reaching the limit of the effect.

The second charge transport layer 35 is formed continuously on the light-emitting layer 34 and on the second conductive portion 33b of the first charge transport layer 33. The second charge transport layer 35 is an electron transport layer, for example. The electron transport layer includes an electron transport material that can stabilize transport of electrons into the light-emitting layer 34. The electron transport layer is an oxide-based transport layer including a metal oxide, for example. The metal oxide preferably includes, for example, at least one selected from the group consisting of zinc oxide (ZnO), aluminum zinc oxide (AlZnO), lithium zinc oxide (LiZnO), and magnesium zinc oxide (MgZnO), and more preferably includes at least one of zinc oxide and magnesium zinc oxide. In particular, zinc oxide and magnesium zinc oxide are generally used as materials for ETL14 and are easily available.

The second electrode 36 is formed continuously on the second charge transport layer 35. The second electrode 36 is appropriately selected from a light-transmissive electrode and a reflective electrode depending on the structure of the light-emitting element and the type of first electrode 31.

Thus, in the light-emitting element according to the present embodiment, the first electrode 31, the first charge transport layer 33, and the light-emitting layer 34 are disposed to overlap each other in this order in the layering direction at least in the light-emitting region ER partitioned by the bank 40. The light-emitting layer 34 is formed at least in the light-emitting region ER and the first region R1 in a plan view of the light-emitting element. When the light-emitting region ER and the first region R1 (first conductive portion 33a) of the first charge transport layer 33 and the second region R2 (second conductive portion 33b) of the first charge transport layer 33, which are disposed along the first direction, are compared, the first conductive portion 33a has a higher electrical conductivity than the second conductive portion 33b.

### Manufacturing Method

Next, a manufacturing method of the light-emitting element according to the present embodiment will be described. The light-emitting element according to the present embodiment can be manufactured by a general film forming technique using a resist, except that a step of defining the electrical conductivity is included in preparing the first charge transport layer 33.

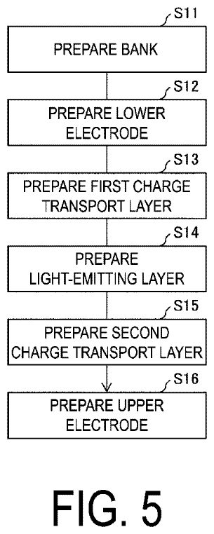

FIG. 5 is a flowchart illustrating an example of a flow of steps for manufacturing the light-emitting element of FIG. 4.

In step S11, the bank 40 is prepared on the substrate 2. The bank 40 can be prepared by applying an ink including a transparent resin to the substrate 2 and then patterning the ink by photolithography.

In step S12, the first electrode 31, which is a lower electrode, is prepared on the substrate 2. The first electrode 31 is prepared by, for example, sputtering through a fine metal mask to sequentially form an Ag layer and an indium tin oxide (ITO) layer.

In step S13, the first charge transport layer 33 is prepared on the first electrode 31 and the bank 40. The first charge transport layer 33 is prepared by preparing a film of a hole transport material and adjusting the electrical conductivity of the film. The preparation of the first charge transport layer 33 will be further described in detail below.

In step S14, the light-emitting layer 34 is prepared on the first charge transport layer 33. The light-emitting layer 34 is prepared by, for example, co-evaporating a host compound and a guest compound (dopant) corresponding to each color through a fine metal mask. The preparation of the light-emitting layer 34 will be further described below.

In step S15, the second charge transport layer 35 is prepared on the light-emitting layer 34 and above the first charge transport layer 33. The second charge transport layer 35 is prepared by, for example, vapor-depositing a hole transport material without using a fine metal mask.

In step S16, the second electrode 36, which is an upper electrode, is prepared on the second charge transport layer 35. The second electrode 36 is prepared by forming a thin film of a magnesium-silver alloy by, for example, a vapor deposition method without using a fine metal mask.

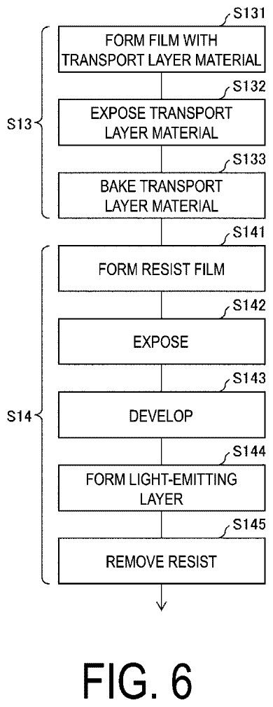

Next, step S13 of preparing the first charge transport layer 33 and step S14 of preparing the light-emitting layer 34 will be further described. FIG. 6 is a flowchart illustrating an example of a flow of steps for preparing the first charge transport layer and the light-emitting layer in FIG. 5. The foregoing step S13 includes, for example, the following steps S131 to S133.

In step S131, a film of a transport layer material of the first charge transport layer 33 is formed on the first electrode 31 and the bank 40. The film of the transport layer material is prepared by, for example, vapor-depositing the organic compound-based material described above without using a fine metal mask.

In step S132, the film of the transport layer material is exposed. Active light rays are used for the exposure. The active light rays are light rays that change the electrical conductivity of the film of the transport layer material, and in the film of the transport layer material, the active light rays exhibit some action of increasing the electrical conductivity of the charge transport layer on molecules of the transport layer material. For example, the active light rays break bonds in the molecules of the transport layer material or cause a photo-rearrangement reaction in the transport layer material. The breaking of the bond, the rearrangement by the reaction, or a new bond formed by a broken site of the bond or an activated site by the reaction can lead to an improvement in the electrical conductivity of the charge transport layer. Examples of the active light rays include ultraviolet rays, X-rays, and gamma rays. From the viewpoint of increasing the electrical conductivity, the active light rays are preferably light rays having a wavelength that cuts an organic bond in the transport layer material.

An irradiation intensity and an irradiation amount in the exposure of the film of the transport layer material are appropriately set according to a strength of the electrical conductivity in the light-emitting region ER, the first region R1, and the second region R2. A region having a higher electrical conductivity (for example, the light-emitting region ER and the first region R1) is irradiated with active light rays at one or both of an increased irradiation intensity and an increased irradiation amount, and a region having a lower electrical conductivity (for example, the second region R2) is irradiated with active light rays at one or both of a decreased irradiation intensity and a decreased irradiation amount.

The irradiation intensity and the irradiation amount of the active light rays can be appropriately adjusted according to a cumulative irradiation amount of the region irradiated with the active light rays. The cumulative irradiation amount is a sum of all irradiation amounts of active light rays with which the film of the transport layer material is irradiated while the light-emitting element is manufactured. For example, the cumulative irradiation amount may include not only the irradiation amount of the active light rays irradiated in step S13 described above, but also the irradiation amount of the active light rays irradiated in preparing the light-emitting layer in step S14.

The cumulative irradiation amount may be determined according to the electrical conductivity of each region of the first charge transport layer 33 irradiated with the active light rays. The cumulative irradiation amount can be increased by increasing the irradiation intensity or the irradiation amount of the active light rays, and can be decreased by decreasing the irradiation intensity or the irradiation amount of the active light rays, or by partially blocking the active light rays with a mask. For example, in step S132, the film of the transport layer material is irradiated with active light rays (for example, ultraviolet rays) through a mask shielding the second region R2 from light. As a result, the electrical conductivity of the second region R2 is the same as an electrical conductivity σ0 before exposure, and the electrical conductivity of the light-emitting region ER and the first region R1 irradiated with the active light rays is the electrical conductivity σ1 higher than the electrical conductivity σ0 before exposure.

In step S133, the film of the transport layer material is baked. Conditions of the baking may be appropriately determined within a range in which the electrical conductivity of the film of the transport layer material is increased. For example, a baking temperature may be 30 to 300° C. from the viewpoint of increasing the electrical conductivity of the film and preventing deformation of the film of the transport layer material. From the viewpoint of increasing the electrical conductivity, the baking temperature is preferably equal to or higher than a crosslinking temperature of the transport layer material (more preferably, the crosslinking temperature +50° C. or lower) in a case where the transport layer material has crosslinkability. A baking time period may be 10 seconds to 10 hours from the above viewpoint. The film may be baked in an atmosphere of an inert gas such as nitrogen from the viewpoint of suppressing oxidation of the film of the transport layer material due to baking. As a result of step S133, an overall electrical conductivity of the film of the transport layer material is the electrical conductivity σ2, that is higher than the electrical conductivity prior to the bake by the increment due to the bake.

Next, step S14 described above is performed. Step S14 described above includes, for example, the following steps S141 to S145.

In step S141, a film of a resist is formed on the first charge transport layer 33. The resist film is prepared by, for example, applying the resist to the first charge transport layer 33 and drying the resist.

In step S142, the resist film is exposed. The resist film is exposed by irradiating a position of the light-emitting layer of one color of R, G, and B in the resist film with active light rays through a fine metal mask having an opening at the position of the light-emitting layer of the one color. For example, in a case of exposure for preparing the red light-emitting layer 34R, the resist film is irradiated with active light rays through a fine metal mask having openings at the positions of the light-emitting region ERR and the first region RIR adjacent thereto. In a case of exposure for preparing the green light-emitting layer 34G, the resist film is irradiated with active light rays through a fine metal mask having openings at the positions of the light-emitting region ERG and the first region R1G adjacent thereto. In a case of exposure for preparing the blue light-emitting layer 34B, the resist film is irradiated with active light rays through a fine metal mask having openings at the positions of the light-emitting region ERB and the first region R1B adjacent thereto. The active light rays may be the same as or different from the active light rays used in step S132 described above. As a result of such exposure, the resist film becomes soluble, and the electrical conductivity of the first charge transport layer 33 (portion of the film of the transport layer material that becomes the first conductive portion 33a) in the light-emitting region ER and the first region R1 irradiated with the active light rays becomes an electrical conductivity σ3 higher than the electrical conductivity σ2 after baking by an amount of irradiation of the active light rays resulting from the exposure of the resist.

In step S143, the exposed resist film is developed. The resist film is developed by, for example, spraying an alkaline developing solution onto the resist film, and as a result, a resist mask (template) through which only the positions of the light-emitting layers to be formed (that is, the portions of the first charge transport layer 33 where the electrical conductivity reaches o3) are exposed is prepared.

In step S144, the light-emitting layer is formed via the developed resist film. In a case where a resist mask through which a portion corresponding to the red light-emitting layer 34R is exposed is prepared, as described above, the red light-emitting layer 34R is prepared by co-evaporating a guest compound (dopant) and a host compound corresponding to red through a fine metal mask, for example.

Note that the light-emitting layer can also be prepared by applying a composition of a light-emitting layer material by ink jet, slit coating, bar coating, spray coating, or the like. In such a case, as the solvent of the composition, a solvent (for example, a low polar solvent) which does not dissolve the resist is preferably used.

In step S145, the resist film is removed. The resist film (for example, a red template) is removed by, for example, spraying and applying a resist stripper on the resist film and washing the resist film.

Steps S141 to S145 are repeatedly performed for each color of the light-emitting layer. As a result, the first conductive portion 33a having the electrical conductivity σ3, the light-emitting layer 34 formed thereon, and the second conductive portion 33b having the electrical conductivity 00 and being adjacent to the first conductive portion 33a, are prepared. Thus, in the above-described manufacturing method, the portions corresponding to the first region and the second region to be formed in the layer formed of the charge transport material whose electrical conductivity changes by irradiation with active light rays are irradiated with a specific cumulative irradiation amount (including substantially zero) of active light rays corresponding to the electrical conductivity of the first region and the second region. The layer formed of the charge transport material is irradiated with the active light rays through a mask and through a template for forming the light-emitting layer.

### Main Actions and Effects of Present Embodiment

Normally, charges are likely to concentrate at the edge portion of the light-emitting element. The edge portion is a portion where the shape of the layer in the light-emitting element changes from the first direction to the layering direction, and is, for example, a boundary portion between the first electrode 31 and the bank 40, or a boundary portion between the inclined surface and the upper face of the bank 40. This is because the charges move not only straight in a depth direction (the layering direction or the electric field direction) but also in a transverse direction (the first direction). Therefore, the charges are less likely to move in the transverse direction at the edge portion, and are concentrated at the edge portion. As a result, for example, the charges are concentrated on an edge portion of the light-emitting layer, and the light-emitting layer material is deteriorated, so that the element lifetime may be shortened.

In the light-emitting element according to the present embodiment, the first conductive portion 33a having a high electrical conductivity in the first charge transport layer 33 extends to the first region R1 further outside the light-emitting region ER. The second region R2 having a lower electrical conductivity is formed further outside the first region R1. Therefore, the charges moving in the transverse direction are likely to move to the outside of the light-emitting region ER, and the concentration of the charges on the edge portion of the light-emitting layer is suppressed. Therefore, deterioration of the light-emitting layer material due to charge concentration in the light-emitting region ER is suppressed. Consequently, the element lifetime is improved as compared with a light-emitting element without the first conductive portion 33a.

In the light-emitting element according to the present embodiment, the region having a high electrical conductivity in the charge transport layer under the light-emitting layer is formed in a range wider than the light-emitting region ER (contact portion between the first electrode 31 and the first charge transport layer 33). The region of the charge transport layer having a high electrical conductivity and the end portion of the light-emitting layer in the first direction are substantially aligned with each other. When the end portion overlaps with the above region, the region with a high electrical conductivity is not in contact with a layer other than the light-emitting layer. Therefore, it is possible to prevent the luminous efficiency from being lowered due to injection of the charge into a layer other than the light-emitting layer. As a result, in the light-emitting element according to the present embodiment, carriers are easily moved due to high electrical conductivity, and thus, the efficiency of charge injection into the light-emitting layer 34 is improved. Therefore, a decrease in luminous efficiency due to the movement of the charge in the first direction does not occur, and further improvement in luminous efficiency due to improvement in charge injection efficiency is expected. As a result, according to the present embodiment, it is possible to increase the reliability of the light-emitting element in exhibiting the desired light-emission characteristics with the current while supplying an appropriate amount of current to the light-emitting region for light emission. For example, a deterioration or a variation of the light-emission characteristics due to the deterioration of the light-emitting layer material caused by the charge concentration at the edge portion is suppressed, and the stability of the light emission with the desired light-emission characteristics is enhanced.

In the light-emitting element according to the present embodiment, a thickness of the edge portion of the light-emitting layer 34 located at the edge portion of the upper surface of the bank 40 is thicker than a thickness of the other portion of the light-emitting layer 34. Therefore, the charges moving in the first direction through the first conductive portion 33a are prevented from moving in the layering direction from the boundary portion with the second conductive portion 33b to the second charge transport layer 35 and the second electrodes 36. As a result, the occurrence of a problem due to such further movement of the charge in the layering direction is suppressed, and thus, it is advantageous from the viewpoint of increasing the reliability of the light-emitting element.

### Second Embodiment

A second embodiment of the disclosure will be described below. Note that, for convenience of description, members having the same functions as those of the members described in the above-described embodiment will be denoted by the same reference numerals and signs, and descriptions thereof will not be repeated. The description of the same action and effect as those of the above-described embodiment will not be repeated. Note that in the present embodiment, a direction indicated by the arrow B-B′ in FIG. 3 is referred to as the “first direction”, and a direction indicated by the arrow A-A′ is referred to as the “second direction”.

The light-emitting element according to the present embodiment has the following two features. The light-emitting element according to the present embodiment is configured in much the same way as the light-emitting element according to the first embodiment described above except for the following two features.
In the first direction, the first region of the charge transport layer has a higher electrical conductivity than the second region of the charge transport layer.
In the second direction, the first region of the charge transport layer has the same electrical conductivity as the second region of the charge transport layer, and the edge portion of the light-emitting layer overlaps another light-emitting layer on the bank.

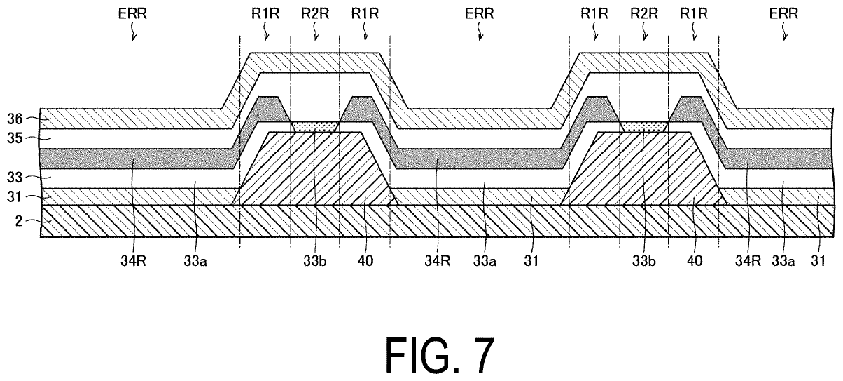

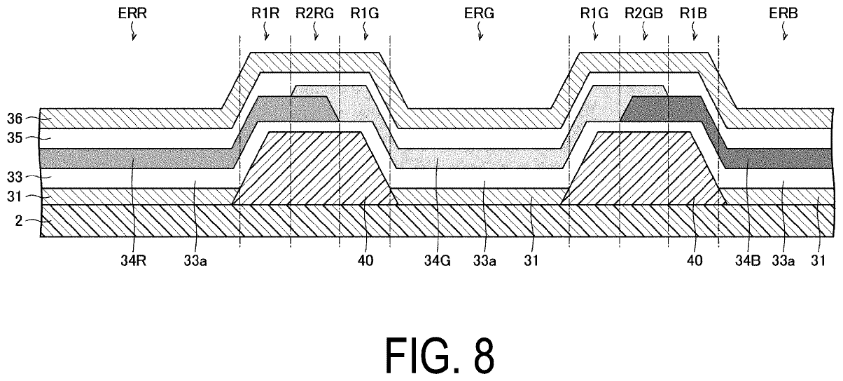

FIG. 7 is a diagram schematically illustrating a cross-sectional structure obtained when the light-emitting element according to the second embodiment of the disclosure is taken along the B-B′ line of FIG. 3. FIG. 8 is a diagram schematically illustrating a cross-sectional structure obtained when the light-emitting element according to the second embodiment of the disclosure is taken along the A-A′ line of FIG. 3.

As illustrated in FIG. 7, in the light-emitting element of each color according to the present embodiment, the first charge transport layer 33 includes the first conductive portion 33a in the first region R1, and includes the second conductive portion 33b in the second region R2, in the first direction. The first conductive portion 33a is a portion having a higher electrical conductivity than the second conductive portion 33b. Similarly to the first embodiment, the first conductive portion 33a and the second conductive portion 33b are formed by exposing the film of the transport layer material through a mask shielding the second region R2 from light in the first direction.

As illustrated in FIG. 8, in the light-emitting element of each color according to the present embodiment, in the second direction, the first charge transport layer 33 includes only the first conductive portion 33a, that is, the same electrical conductivity. In the second region R2, edge portions of the adjacent light-emitting layers overlap each other. That is, in a second region R2RG between the red light-emitting region ERR and the green light-emitting region ERG, the edge portion of the green light-emitting layer 34G overlaps the edge portion of the red light-emitting layer 34R. In a second region R2GB between the green light-emitting region ERG and the blue light-emitting region ERB, the edge portion of the green light-emitting layer 34G overlaps the edge of the blue light-emitting layer 34B.

The light-emitting element according to the present embodiment is manufactured in much the same way as in the first embodiment described above except for the following two points.
In step S132 described above, the film of the transport material is exposed through a mask shielding a portion corresponding to the second region R2 from light in both the first direction and the second direction.
In step S142 described above, the resist is exposed through a mask opening in the second direction to the light-emitting region ER, the first region R1, and the second region R2.

The mask used in step S142 of the present embodiment may be a mask shielding the second region (for example, the second region R2R in a case of the red light-emitting element) in the first direction from light, or may be a mask having an opening in the second region. From the viewpoint of increasing a difference in electrical conductivity between the first conductive portion 33a and the second conductive portion 33b in the first direction and from the viewpoint of further reducing the electrical conductivity of the second conductive portion 33b, it is preferable to use the mask shielding the second region in the first direction from light.

First, by the exposure in step S132, in both the first direction and the second direction, the second conductive portion 33b of the first charge transport layer 33 has the electrical conductivity σ0 before the exposure, and the electrical conductivity of the first conductive portion 33a becomes the electrical conductivity σ1 higher than the electrical conductivity σ0. In a case where a mask shielding the second region R2 in the first direction from light is used for the exposure in step S142, the electrical conductivities of the light-emitting region ER and the first region R1 become the electrical conductivity σ2 higher than the electrical conductivity σ1, and the electrical conductivity of the second region R2 remains the electrical conductivity σ0.

Even when a mask not shielding the second region R2 in the first direction is used, the electrical conductivity of the second region R2 is the electrical conductivity ol lower than the electrical conductivity σ2.

By the exposure in step S142, in the second direction, the light-emitting region ER and the first region R1 are exposed once in each of step S132 and step S142, and the electrical conductivity of such regions reaches the electrical conductivity σ2 higher than the electrical conductivity σ1. The second region R2 is exposed twice in step S142 to receive each of the exposures for the adjacent light-emitting layers in step S142. As a result, the electrical conductivity of the second region R2 is the electrical conductivity σ2 higher than the electrical conductivity σ1. Therefore, in the second direction, the electrical conductivity of the first charge transport layer 33 is the same electrical conductivity σ2 in any region.

In the present embodiment, the electrical conductivity of the first charge transport layer 33 in the second direction is the highest electrical conductivity σ2, and thus, the charge is likely to spread in the second direction. Therefore, it is possible to provide a further enhanced effect from the viewpoint of suppressing the concentration of the charge at the edge portion.

In the first direction, the electrical conductivity of the second region R2 is the lower electrical conductivity σ0 or σ1, and thus, the leakage of the charge to the upper layer in the layering direction is suppressed as in the first embodiment. Therefore, a variation or a reduction in the light-emission characteristics or electrical characteristics of the light-emitting element due to the leakage of the charge is suppressed, which provides a further enhanced effect from the viewpoint of realizing stable driving of the light-emitting element exhibiting a desired function.

### Third Embodiment

A third embodiment of the disclosure will be described below. Note that, for convenience of description, members having the same functions as those of the members described in the above-described embodiments will be denoted by the same reference numerals and signs, and descriptions thereof will not be repeated. The description of the same action and effect as those of the above-described embodiment will not be repeated. In the present embodiment, as in the second embodiment, the direction indicated by the arrow B-B′ in FIG. 3 is referred to as the “first direction”, and the direction indicated by the arrow A-A′ is referred to as the “second direction”. The light-emitting element according to the present embodiment has the following two features. The light-emitting element according to the present embodiment is configured in much the same way as the light-emitting element according to the first embodiment described above except for the following two features.
In a first direction in a plan view of the light-emitting element, a first region of the charge transport layer has a higher electrical conductivity than a second region of the charge transport layer adjacent to the first region.
In the second direction in a plan view of the light-emitting element, the second region of the charge transport layer has a higher electrical conductivity than the first region of the charge transport layer adjacent to the second region, and the edge portion of the light-emitting layer overlaps another light-emitting layer on the bank (that is, on the second region).

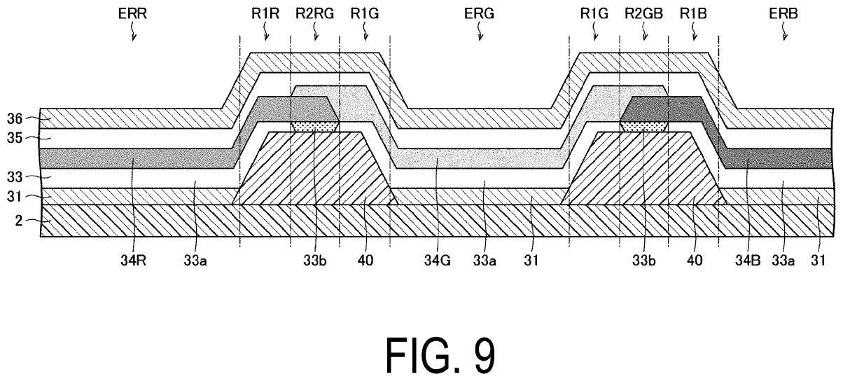

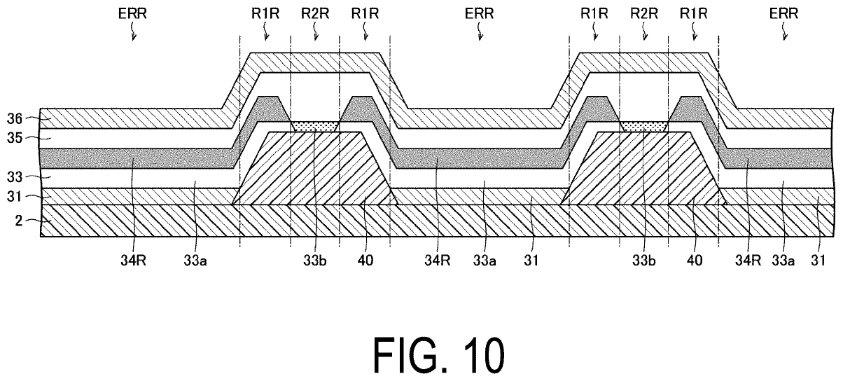

FIG. 9 is a diagram schematically illustrating a cross-sectional structure obtained when the light-emitting element according to the third embodiment of the disclosure is taken along the A-A′ line of FIG. 3. FIG. 10 is a diagram schematically illustrating a cross-sectional structure obtained when the light-emitting element according to the third embodiment of the disclosure is taken along the B-B′ line of FIG. 3.

As illustrated in FIG. 10, in the light-emitting layer of each color of the present embodiment, the first charge transport layer 33 includes the first conductive portion 33a in the first region R1, and includes the second conductive portion 33b in the second region R2, in the first direction, as in the second embodiment.

As illustrated in FIG. 9, in the light-emitting layer of each color of the present embodiment, the first conductive portion 33a of the first charge transport layer 33 has a lower electrical conductivity than the second conductive portion 33b in the second direction. That is, the current flows more easily through the second conductive portion 33b than through the first conductive portion 33a. In the second region R2, edge portions of the adjacent light-emitting layers overlap each other.

The light-emitting element according to the present embodiment is manufactured in much the same way as in the second embodiment described above except for the following two points.
In step S132 described above, a portion corresponding to the second region R2 is shielded from light in the first direction, and the film of the transport material is exposed through a mask having an opening in a portion corresponding to the second region R2 in the second direction.
In step S142 described above, the resist is exposed through a mask opening in the second direction to the light-emitting region ER, the first region R1, and the second region R2.

First, by the exposure in step S132 described above, in the first direction, the second conductive portion 33b of the first charge transport layer 33 has the electrical conductivity σ0 before the exposure, and the electrical conductivity of the first conductive portion 33a becomes the electrical conductivity ol higher than the electrical conductivity σ0. In the second direction, the electrical conductivity of each of the light-emitting region ER, the first conductive portion 33a, and the second conductive portion 33b is the electrical conductivity σ1.

By the exposure in step S142 described above, in the first direction, as in the second embodiment, the electrical conductivity of each of the light-emitting region ER and the first region R1 is the electrical conductivity σ2 higher than the electrical conductivity σ1, and the electrical conductivity of the second region R2 is the electrical conductivity σ0 or the electrical conductivity σ1 according to the mask used in step S142.

By the exposure in step S142 described above, the light-emitting region ER and the first region R1 are exposed once in step S132 and once in step S142 in the second direction. Therefore, the electrical conductivity of each of such regions is the electrical conductivity o2. The second region R2 is exposed once in step S132 and once in step S142 to receive each of the exposures for the adjacent light-emitting layers in step S142. Therefore, the electrical conductivity of the second region R2 in the second direction is the electrical conductivity σ3 much higher than the electrical conductivity σ2.

In the present embodiment, the second conductive portion 33b having a higher electrical conductivity is formed adjacently to the first conductive portion 33a of the first charge transport layer 33 in the second direction. Therefore, the charge is more likely to move in the second direction, and the concentration of the charge at the edge portion is further suppressed. The edge portions of different light-emitting layers are formed on the second conductive portion 33b so as to overlap each other. Thus, the leakage of the charge from the second conductive portion 33b to the upper side is suppressed.

### Fourth Embodiment

A fourth embodiment of the disclosure will be described below. Note that, for convenience of description, members having the same functions as those of the members described in the above-described embodiments will be denoted by the same reference numerals and signs, and descriptions thereof will not be repeated. The description of the same action and effect as those of the above-described embodiment will not be repeated. Note that in the present embodiment, as in the first embodiment, the direction indicated by the arrow A-A′ in FIG. 3 is referred to as the “first direction”. In the display device according to the present embodiment, in the first direction, the first regions of the charge transport layers adjacent to each other via the second region have different electrical conductivities. The display device according to the present embodiment is configured in much the same way as in the first embodiment described above except for such characteristics.

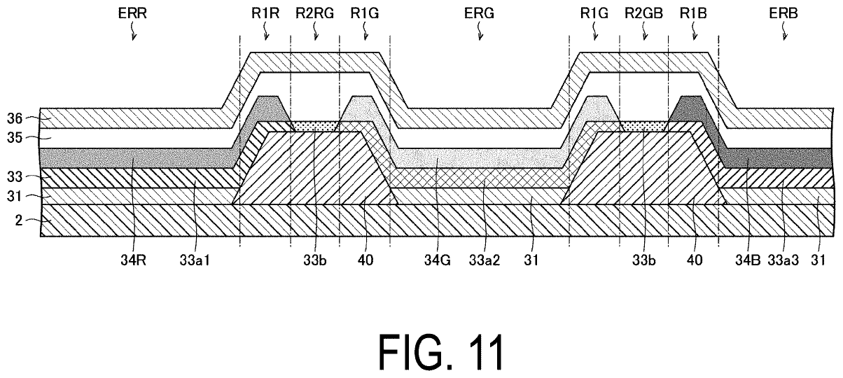

FIG. 11 is a diagram schematically illustrating a cross-sectional structure obtained when a light-emitting element according to the fourth embodiment of the disclosure is taken along the A-A′ line of FIG. 3. As illustrated in FIG. 11, the first charge transport layer 33 common to the light-emitting element of each color in the present embodiment includes three types of first conductive portions 33a and one type of second conductive portion 33b in the first direction. The three types of first conductive portions 33a have electrical conductivities that are higher than the electrical conductivity of the second conductive portion 33b, but have electrical conductivities different from one another. For example, the electrical conductivity of a first conductive portion 33a1 in the red light-emitting element is the highest, the electrical conductivity of a first conductive portion 33a2 in the green light-emitting element is the second highest, and the electrical conductivity of a first conductive portion 33a3 in the blue light-emitting element is the third highest.

The light-emitting element of each color in the present embodiment is manufactured in much the same way as in the first embodiment described above except for an exposure step 1 or an exposure step 2 described below.

### Exposure Step 1

In step S132 described above, the film of the transport material is exposed through a mask shielding a portion corresponding to the second region R2 in the first direction, and the mask has an opening ratio of portions corresponding to the first conductive portions 33a1, 33a2, and 33a3 that decreases in the order of the first conductive portions 33a1, 33a2, and 33a3. A halftone mask is employed for such a mask.

### Exposure Step 2

In step S142 described above, the light-emitting region ERR and the first region R1R in the resist are exposed with active light rays of a first cumulative irradiation amount which is the largest, the light-emitting region ERG and the first region R1G are exposed with active light rays having a second cumulative irradiation amount which is the second largest, and the light-emitting region ERB and the first region R1B are exposed with active light rays having a third cumulative irradiation amount which is the third largest.

In a case of the exposure step 1, in the first direction, the second conductive portion 33b of the first charge transport layer 33 has the electrical conductivity σ0 obtained before the exposure according to step S132 described above. The first conductive portion 33a1 is exposed with active light rays through an opening having the largest opening ratio from among the openings of the mask corresponding to the first conductive portions 33a1 to 33a3. Therefore, the electrical conductivity of the first conductive portion 33a1 is the highest electrical conductivity 63 from among the electrical conductivities of the first conductive portions 33a1 to 33a3. From the relationship of the opening ratio of the mask, the electrical conductivity of the first conductive portion 33a2 is the second highest electrical conductivity σ2, and the electrical conductivity of the first conductive portion 33a3 is the third highest electrical conductivity σ1. The magnitude of the electrical conductivity is in the order of σ3>σ2>σ1>σ0.

By the subsequent exposure according to step S142, the electrical conductivity of the second conductive portion 33b in the first direction is the electrical conductivity 60 or σ1. The electrical conductivity of the first conductive portion 33a1 is an electrical conductivity 64 much higher than the electrical conductivity σ3, the electrical conductivity of the first conductive portion 33a2 is the electrical conductivity σ3, and the electrical conductivity of the first conductive portion 33a3 is the electrical conductivity σ2. The magnitude of the electrical conductivity is in the order of σ4>σ3>σ2>σ1>σ0.

In a case of the exposure step 2, the electrical conductivity of the second conductive portion 33b in the first direction is, for example, the electrical conductivity σ0 or σ1 according to the step S142. Next, for example, the electrical conductivity of the first conductive portion 33al changes from the electrical conductivity σ1 obtained before the exposure to the electrical conductivity 64, the electrical conductivity of the first conductive portion 33a2 changes from the electrical conductivity σ1 obtained before the exposure to the electrical conductivity σ3, and the electrical conductivity of the first conductive portion 33a3 changes from the electrical conductivity σ1 obtained before the exposure to the electrical conductivity σ2.

In the present embodiment, the electrical conductivity of the plurality of first conductive portions 33a can be independently set in the first direction within a range higher than the electrical conductivity of the second conductive portion 33b. Therefore, it is possible to set the ease of movement of the charges in the first direction according to the magnitude of the influence of the concentration of the charges on the edge portion, for example, in the case of a light-emitting layer material that is more likely to deteriorate due to the concentration of the charges.

### Modified Examples

In the embodiments described above, the first charge transport layer may be a hole transport layer or an electron transport layer. In the above-described embodiments, the second charge transport layer may be an electron transport layer or a hole transport layer.

In the embodiment of the disclosure, the light-emitting element may further include other charge transport layers, such as a hole injection layer and an electron injection layer, in addition to the hole transport layer and the electron transport layer described above, within a range in which the effects of the disclosure can be obtained.

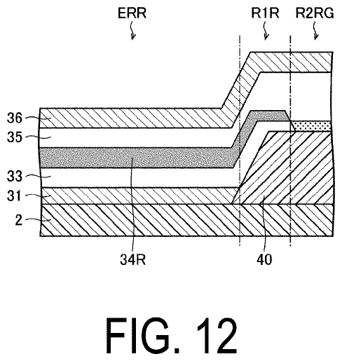

In the embodiment of the disclosure, as illustrated in FIG. 12, the thickness of the light-emitting layer 34 at the edge portion of the first region R1 may not be thicker than (may be about the same as) the thickness of the light-emitting layer 34 at the other portions of the light-emitting layer 34.

In the first embodiment, a step may be omitted as long as a sufficient difference in electrical conductivity is generated between the light-emitting region ER and the first region R1 and the second region R2. For example, in the first embodiment, the portion corresponding to the second region R2 may not be shielded from light during the exposure of the first charge transport layer 33. In such a case, the light-emitting region ER and the first region R1 having the electrical conductivity σ3 and the second region R2 having the electrical conductivity σ2 are formed.

Alternatively, in the first embodiment, the film of the transport layer material of the first charge transport layer 33 may not be baked. In such a case, the light-emitting region ER and the first region R1 having an electrical conductivity of greater than σ1 and less than 3, and the second region R2 having an electrical conductivity of σ0 are formed.

The disclosure is not limited to the embodiments described above, and various modifications may be implemented within a range not departing from the scope of the claims. Embodiments obtained by appropriately combining technical approaches disclosed in each of the different embodiments also fall within the scope of the technology of the disclosure. Furthermore, novel technical features can be formed by combining the technical approaches disclosed in the embodiments.

For example, in the first embodiment and the fourth embodiment, the layer configuration in the second direction may further include a characteristic similar to a characteristic of the layer configuration in the first direction or the layer configuration in the second direction in any one of the embodiments described above as long as it is possible to obtain the effect provided in the disclosure. For example, the first embodiment may further include a characteristic of the layer configuration in the first direction in the first embodiment, in the layer configuration in the second direction.

According to the disclosure, in a display device by electroluminescence, it is possible to realize a further prolonged element lifetime and improvement of a high luminous efficiency and a reliability by appropriately setting regions having different electrical conductivities to the first charge transport layer. Therefore, the light-emitting element and the display device according to the disclosure are expected to contribute to achievement of, for example, Goal 9 “Industry, Innovation, and Infrastructure” of the Sustainable Development Goals (SDGs) advocated by the United Nations.

1. A light-emitting element comprising:
an electrode;
a charge transport layer; and
a light-emitting layer,
the electrode, the charge transport layer, and the light-emitting layer being disposed to overlap in this order in a light-emitting region partitioned by at least a bank,
wherein the charge transport layer is formed in the light-emitting region, a first region adjacent to an outer side of the light-emitting region, and a second region adjacent to a further outer side of the first region, in a plan view,
the light-emitting layer is formed in at least the light-emitting region and the first region in a plan view,
in at least one direction in a plan view, the light-emitting region and the first region of the charge transport layer have a higher electrical conductivity than the second region of the charge transport layer, and
in the first region, the light-emitting layer has an edge portion having a thickness larger than a thickness in the light-emitting region.

2. A light-emitting element comprising:
an electrode;
a charge transport layer; and
a light-emitting layer,
the electrode, the charge transport layer, and the light-emitting layer being disposed to overlap in this order in a light-emitting region partitioned by at least a bank,
wherein the charge transport layer is formed in the light-emitting region, a first region adjacent to an outer side of the light-emitting region, and a second region adjacent to a further outer side of the first region, in a plan view,
the light-emitting layer is formed in at least the light-emitting region and the first region in a plan view,
in at least one direction in a plan view, the light-emitting region and the first region of the charge transport layer have a higher electrical conductivity than the second region of the charge transport layer, and
in a second direction intersecting the at least one direction plan view, the first region of the charge transport layer has the same electrical conductivity as the second region of the charge transport layer, and an edge portion of the light-emitting layer overlaps another light-emitting layer on the bank.

3. A light-emitting element comprising:
an electrode;
a charge transport layer; and
a light-emitting layer,
the electrode, the charge transport layer, and the light-emitting layer being disposed to overlap in this order in a light-emitting region partitioned by at least a bank,
wherein the charge transport layer is formed in the light-emitting region, a first region adjacent to an outer side of the light-emitting region, and a second region adjacent to a further outer side of the first region, in a plan view,
the light-emitting layer is formed in at least the light-emitting region and the first region in a plan view,
in at least one direction in a plan view, the light-emitting region and the first region of the charge transport layer have a higher electrical conductivity than the second region of the charge transport layer, and
in a second direction intersecting the at least one directionin the second region of the charge transport layer has a higher electrical conductivity than the first region of the charge transport layer, and an edge portion of the light-emitting layer overlaps another light-emitting layer on the bank.

4. (canceled)

5. The light-emitting element according to claim 1,
wherein the bank has a trapezoidal cross-sectional shape, and
the first region is a region from an inclined surface of the bank to an edge portion of an upper face of the bank in a plan view.

6. The light-emitting element according to claim 1,
wherein in at least one direction in the plan view, electrical conductivities of the light-emitting region and the first region of the charge transport layer are equal to or greater than 10⁻¹⁰ S/m and equal to or less than 10^{'}S/m, and an electrical conductivity of the second region of the charge transport layer is equal to or greater than 10⁻¹² S/m and equal to or less than 10⁻⁵ S/m.

7. A manufacturing method of the light-emitting element according to claim 1, comprising:
irradiating a portion corresponding to each of the first region and the second region to be formed in a layer formed of a charge transport material with an electrical conductivity varying when irradiated with active light rays, with active light rays having a specific cumulative irradiation amount according to electrical conductivities of the first region and the second region.

8. The manufacturing method of the light-emitting element according to claim 7,
wherein the irradiating with active light rays includes irradiating a layer formed of the charge transport material, with active light rays, via a mask.

9. The manufacturing method of the light-emitting element according to claim 7,
wherein the irradiating with active light rays includes irradiating a layer formed of the charge transport material with active light rays, via a template for forming the light-emitting layer.

10. A display device comprising:
the light-emitting element according to claim 1.

11. The display device according to claim 10, comprising:
a plurality of the light-emitting elements,
wherein in at least one of a first direction in the plan view and a second direction intersecting the first direction, the first region of the charge transport layer and the first region of the charge transport layer adjacent each other via the second region have electrical conductivities different from each other.
